(19) United States
(12) Patent Application Publication
(10) Pub. No.: US 2026/0262332 A1
(43) Pub. Date: Sep. 3, 2026

(54) TWISTING METHOD OF POST LASER LIFT-OFF SAPPHIRE REMOVAL

(71) Applicant: Lumileds LLC, San Jose, CA (US)

(72) Inventors: Joyce Chan Li Kin, Singapore (SG); Chee Chung James Wong, Singapore (SG); Yeow Meng Teo, Singapore (SG)

(73) Assignee: Lumileds LLC, San Jose, CA (US)

(21) Appl. No.: 18/994,769

(22) PCT Filed: Aug. 18, 2023
(86) PCT No.: PCT/US2023/030612

§ 371 Date: Jan. 15, 2025

Related U.S. Application Data
(60) Provisional application No. 63/371,975, filed on Aug. 19, 2022.

(51) Int. Cl. H10H 20/01

(52) U.S. Cl. CPC H10H 20/019

(57) ABSTRACT

A light emitting diode (LED) device sapphire substrate removal apparatus and method are disclosed. The method includes placing the LED device comprising a sapphire substrate and a carrier onto a holding plate sized and shaped to hold the carrier of the LED device and applying a twisting force to the sapphire substrate to separate the sapphire substrate from the carrier. The apparatus includes the holding plate and a sapphire substrate removal tool.

### TECHNICAL FIELD

Embodiments of the disclosure generally relate to light emitting devices, and in particular, post laser lift-off of materials and structures for removing layers, such as sapphire substrates, from light emitting diode (LED) devices during the manufacture of LEDs.

### BACKGROUND

Layers are commonly grown on a carrier or a substrate, such as a sapphire substrate, to form LEDs. A few examples of epitaxial (EPI) layer materials include gallium nitride (GaN), aluminum gallium nitride (AlGaN), aluminum nitride (AlN), indium nitride (InN) and indium gallium nitride (InGaN). In this disclosure, a GaN layer will be used as a non-limiting example for an exemplary description of a laser lift-off (LLO) process.

As shown in FIG. 1, a prior art laser lift-off process 100 is used to separate a substrate, such as a sapphire substrate 104, from a GaN interface 106 of an LED device 101 using a laser source 102. The sapphire substrate 104 is on the GaN interface 106, which is on an interconnect 108, which is mounted on a carrier 110 (which can also be referred to as a sub-mount or sub-mount tile), such that the interconnect 108 is disposed between the GaN interface 106 and the carrier 110. This technique has been used to increase the luminous efficiency of GaN-based LEDs. The sapphire substrate 104, the GaN interface 106, and the interconnect 108 are bonded onto the carrier 110 by an underfill adhesive disposed between the interconnect 108 and the carrier 110. Conventional laser lift-off methods used in LED manufacturing processes use a single shot laser beam. The laser source 102 generates a laser beam that is directed towards and passes through the sapphire substrate 104 and is absorbed by the GaN interface 106 at high temperatures. Thermal decomposition of the GaN interface 106 occurs when high energy from the laser source 102 induces local heating on the GaN interface 106 above the critical sublimation temperature of gallium (Ga), forming metallic Ga and gaseous nitrogen (Np) as shown in the equation: 2GaN(s)→2Ga(l)+N₂(g). Removal of the sapphire substrate 104 occurs via the instantaneous N₂ vaporization pressure generated, which lifts the sapphire substrate 104 from the GaN interface 106.

A challenge in sapphire substrate removal is that sapphire can be melted onto the GaN interface layer during the laser lift-off process. In some instances, the sapphire substrate melts and forms one or more forms of alumina (aluminum oxide), for example, crystalline alumina such as alpha alumina or polycrystalline alumina or amorphous alumina. These different forms of alumina form at high temperature due to partial transmission and reflection amplitudes when the laser moves from a low (sapphire) to high (GaN) refractive index medium, causing rapid cooling. When rapid cooling occurs, the alumina will stick to the GaN and sapphire surfaces. This may cause the sapphire substrate to remain intact and prevent the laser lift-off from removing the sapphire substrate from the GaN interface.

There is a need to address the challenges of sapphire substrate removal after a laser lift-off process in which the sapphire substrate remains adhered to the GaN interface.

### SUMMARY

An aspect of the disclosure pertains to a method of removing a sapphire substrate from an LED device, the method comprising placing the LED device comprising a sapphire substrate and a carrier onto a holding plate sized and shaped to hold the carrier of the LED device; and applying a twisting force to the sapphire substrate to separate the sapphire substrate from the carrier.

Embodiments according to this aspect can include one or more of the following features. The method can further comprise affixing the holding plate to a support prior to applying the twisting force to prevent the holding plate from twisting when removing the sapphire substrate from the LED device. A sapphire substrate removal tool is utilized to apply the twisting force to the sapphire substrate. The method further comprises applying suction to the sapphire substrate removal tool to pick the LED device from a first location and place the LED device onto the holding plate. The method further comprises using a motor to rotate the sapphire substrate removal tool. The holding plate comprises a recessed region defining an area configured to receive the carrier and a raised edge configured to hold the carrier while removing the sapphire substrate from the LED device, and placing the LED device onto the holding plate comprises placing the carrier into the recessed region defining the area such that the raised edge holds the carrier. The sapphire substrate removal tool comprises a base including a first rail spaced apart from a second rail, the first rail and the second rail defining an area sized and shaped to surround the sapphire substrate and configured to remove the sapphire substrate from the LED device when the sapphire substrate removal tool is twisted to separate the sapphire substrate from the carrier, and the method further comprises, prior to applying the twisting force to the sapphire substrate, positioning the first rail and second rail to surround the sapphire substrate. The raised edge comprises at a first edge portion separated from a second edge portion at a distance and configured to hold the carrier while removing the sapphire substrate from the LED device. The first edge portion is separated from the second edge portion at a distance in a range of from about 1 millimeter to about 300 millimeters. The first edge portion is separated from the second edge portion at a distance in a range of from about 2 millimeters to about 25 millimeters. The raised edge comprises a peripheral edge defining an area configured to hold the carrier while removing the sapphire substrate from the LED device. The area is sized to hold the carrier having a length or a width dimension in a range from about 1 millimeter to about 300 millimeters. The area is sized to hold the carrier having a length or a width dimension in a range from about 2 millimeters to about 25 millimeters. The sapphire substrate removal tool comprises a metal. The sapphire substrate removal tool further comprises a first post and a second post extending from the base. At least one of the first post and the second post are hollow. The method further comprises attaching a vacuum suction connection to at least one of the first post and the second post. A rotatable tool is configured to engage with the sapphire substrate removal tool, and applying the twisting force to the sapphire substrate comprises causing the rotatable tool to rotate the sapphire substrate removal tool. The rotatable tool comprises a motor and a shaft connected to the motor and connectable to the sapphire substrate removal tool. The sapphire substrate removal tool and the holding plate are configured to be movable vertically with respect to each other, and applying a twisting force to the sapphire substrate to separate the sapphire substrate from the carrier further comprises moving the sapphire substrate removal tool and the holding plate vertically with respect to each other to separate the sapphire substrate from the carrier.

### BRIEF DESCRIPTION OF THE DRAWINGS

So that the manner in which the above recited features of the present disclosure can be understood in detail, a more particular description of the disclosure, briefly summarized above, may be had by reference to embodiments, some of which are illustrated in the appended drawings. It is to be noted, however, that the appended drawings illustrate only typical embodiments of this disclosure and are therefore not to be considered limiting of its scope, for the disclosure may admit to other equally effective embodiments. The embodiments as described herein are illustrated by way of example and not limitation in the figures of the accompanying drawings in which like references indicate similar elements. The figures herein are not to scale.

FIG. 1 is a schematic view illustrating a prior art laser lift-off process to remove a sapphire substrate from a light emitting diode die;

FIG. 2A is a top perspective view of a holding plate portion of a light emitting diode (LED) device sapphire substrate removal apparatus according to one or more embodiments;

FIG. 2B is a bottom perspective view of a sapphire substrate removal tool portion of the light emitting diode (LED) device sapphire substrate removal apparatus shown in FIG. 2A;

FIG. 2C is a perspective view of a light emitting diode (LED) device sapphire substrate removal apparatus according to one or more embodiments;

FIG. 2D is an alternate perspective view of the light emitting diode (LED) device sapphire substrate removal apparatus shown in FIG. 2C according to one or more embodiments;

FIG. 3A is a perspective view of a light emitting diode (LED) device sapphire substrate removal apparatus shown during a sapphire substrate removal process according to one or more embodiments;

FIG. 3B is an alternate perspective view of the light emitting diode (LED) device sapphire substrate removal apparatus shown in FIG. 3A during a sapphire substrate removal process according to one or more embodiments;

FIG. 4A is a perspective view of a light emitting diode (LED) device sapphire substrate removal apparatus shown during a sapphire substrate removal process according to one or more embodiments;

FIG. 4B is a perspective view of a light emitting diode (LED) device sapphire substrate removal apparatus shown during a sapphire substrate removal process during twisting of the sapphire substrate according to one or more embodiments;

FIG. 4C is a perspective view of a light emitting diode (LED) device sapphire substrate removal apparatus shown during a sapphire substrate removal process after the sapphire substrate has been removed according to one or more embodiments;

FIG. 5A is a side view of a light emitting diode (LED) device sapphire substrate removal apparatus shown during a sapphire substrate removal process according to one or more embodiments;

FIG. 5B is a side view of the light emitting diode (LED) device sapphire substrate removal apparatus shown in FIG. 5A during a sapphire substrate removal process according to one or more embodiments with a portion of the holding plate exposed to show the LED device in the holding plate;

FIG. 6 is a graph illustrating the effect of applied forces by the twisting method and apparatus according to one or more embodiments;

FIG. 7 is a flow chart illustrating a method according to one or more embodiments; and

FIG. 8 is a perspective view illustrating removal of a sapphire substrate from an LED die including a trenched metal grid.

### DETAILED DESCRIPTION

Before describing several exemplary embodiments of the disclosure, it is to be understood that the disclosure is not limited to the details of construction or process steps set forth in the following description. The descriptions in the disclosure are capable of other embodiments and of being practiced or being carried out in various ways.

Reference to an LED (or the plural, LEDs) refers to a light emitting diode device at the wafer or the die level that emits light when current flows through the LED. In one or more embodiments, the LEDs herein have one or more characteristic dimensions (e.g., height, width, depth, thickness, etc. dimensions). In one or more embodiments, the length and the width are in a range from about 1 mm to about 350 mm. In one or more embodiments, one or more dimensions of height, width, depth, and thickness have values in a range of from about 1 mm to about 300 mm, from about 1 mm to about 150 mm, or from about 1 mm to about 100 mm. LED devices according to some embodiments include micro-LEDs (uLEDs or μLEDs), referring to a light emitting diode having one or more characteristic dimensions (e.g., height, width, depth, thickness, etc. dimensions) of less than 100 micrometers. In one or more embodiments, one or more dimensions of height, width, depth, and thickness of an LED die have values in a range of from about 1 mm to about 300 mm, for example, from about 1 mm to about 75 mm, for example from about 1 mm to about 50 mm, from about 1 mm to about 25 mm, from about 2 mm to about 25 mm, or from about 3 mm to about 15 mm. Overall, in one or more embodiments, the LEDs herein may have a characteristic length and width dimension ranging from about 1 mm to about 350 mm, and all values and sub-ranges therebetween. The thickness dimension of various semiconductor layers and the sapphire substrate may be expressed in micrometers. For example, in some embodiments, the semiconductor layers (such as the GaN interface 106) discussed herein have a thickness in a range of from about 2 μm to about 50 μm, for example from about 2 μm to about 30 μm, or about 2 μm to about 20 μm. In some embodiments, the thickness of the sapphire substrate 104 is in a range of from about 100 μm to about 800 μm.

LEDs capable of operation across the visible spectrum include Group III-V semiconductors, particularly binary, ternary, and quaternary alloys of gallium, aluminum, indium, and nitrogen, also referred to as Ill-nitride materials. Typically, III-nitride light emitting devices are fabricated by epitaxially growing a stack of semiconductor layers of different compositions and dopant concentrations on a growth substrate such as a sapphire, silicon carbide, Ill-nitride, or other suitable substrate by metal-organic chemical vapor deposition (MOCVD), molecular beam epitaxy (MBE), or other epitaxial techniques. Sapphire is often used as the growth substrate due to its wide commercial availability and relative ease of use. The stack grown on the growth substrate typically includes one or more n-type layers doped with, for example, Si, formed over the substrate, a light emitting or active region formed over the n-type layer or layers, and one or more p-type layers doped with, for example, Mg, formed over the active region. An LED die is a structure including a substrate and the stack of semiconductor layers.

Methods of depositing materials, layers, and thin films to form LEDs include but are not limited to: sputter deposition, atomic layer deposition (ALD), chemical vapor deposition (CVD), physical vapor deposition (PVD), plasma enhanced atomic layer deposition (PEALD), plasma enhanced chemical vapor deposition (PECVD), and combinations thereof.

Methods of forming or growing semiconductor layers including n-type layers, active regions, and p-type layers can be in accordance with methods known in the art. In one or more embodiments, the semiconductor layers are formed by epitaxial (EPI) growth. The semiconductor layers according to one or more embodiments comprise epitaxial layers, Ill-nitride layers, or epitaxial Ill-nitride layers. In one or more embodiments, the semiconductor layers comprise a Ill-nitride material, and in specific embodiments, an epitaxial Ill-nitride material. In some embodiments, the Ill-nitride material comprises one or more of gallium (Ga), aluminum (Al), and indium (In). Thus, in some embodiments, the semiconductor layers comprise one or more of gallium nitride (GaN), aluminum nitride (AlN), indium nitride (InN), aluminum gallium nitride (AlGaN), indium gallium nitride (InGaN), indium aluminum nitride (InAlN), aluminum indium gallium nitride (AlInGaN), and the like. The Ill-nitride materials may be doped with one or more of silicon (Si), oxygen (O), boron (B), phosphorus (P), germanium (Ge), manganese (Mn), or magnesium (Mg) depending upon whether p-type or n-type III-nitride material is needed. In one or more embodiments, the semiconductor layers have a combined thickness in a range of from about 2 μm to about 10 μm, and all values and subranges therebetween.

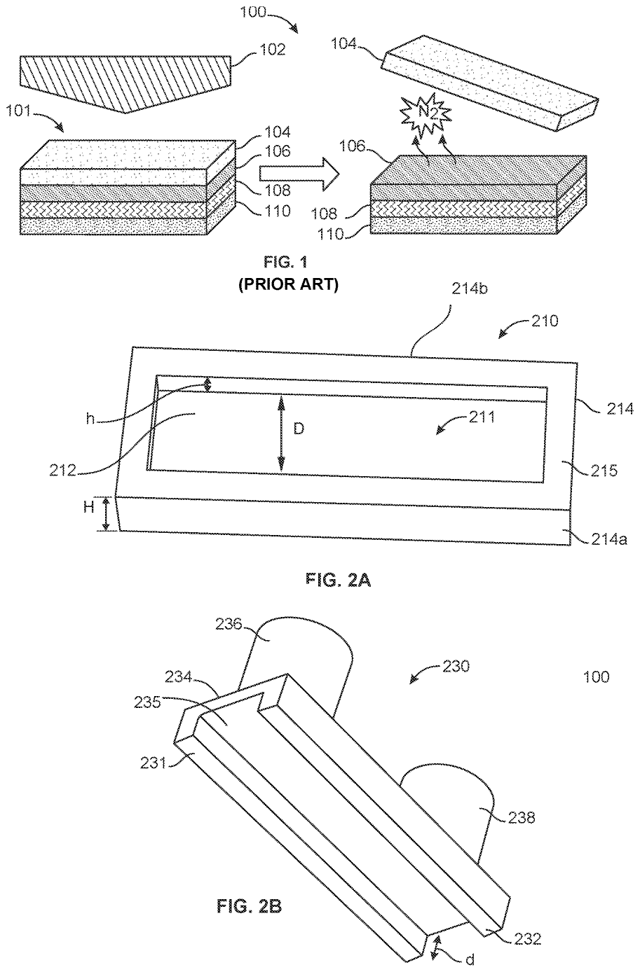

Thus, according to one or more embodiments, in the manufacture of an LED, a GaN interface is formed on a sapphire substrate, followed by one or more n-type layers, one or more active layers, and one or more p-type layers that form the interconnect 108 (e.g., as shown in FIG. 1). Metallic conductors may be formed through and upon one or more of the layers to provide coupling of the n-type and p-type layers to an external source of power to activate the active layer(s) of the light emitting element, via contact pads above the uppermost (p-type) layer.

As discussed above, laser lift-off is a process that is commonly used to remove the sapphire substrate from an LED device. A laser pulse is projected toward and through the sapphire substrate and is absorbed by the semiconductor layer at the sapphire-semiconductor interface, causing thermal decomposition of the semiconductor layer at the interface. The laser pulse in some embodiments comprises multiple pulsed laser shots that are stitched together (e.g., by raster scanning multiple smaller laser beams) to cover an entire area of a sapphire substrate that is removed at the wafer level or from a die comprising multiple LEDs. In other embodiments, the laser pulse is a single shot laser that covers the entire area of a sapphire substrate that is removed at the wafer level or from a die comprising multiple LEDs. In a specific embodiment, a single shot laser is used, comprising an ArF excimer laser with a flat top beam having a beam size in a range from 1 mm×1 mm to 2.2 mm×2.7 mm, which is useful for dies up to 2.2 mm×2.7 mm (width×length). In another specific embodiment, a KrF excimer laser is used for laser lift-off of a micro-LED, using a flat top laser beam having a beam size in a range from 200 micrometers×200 micrometers to 500 micrometers×500 micrometers. By using beam stitching, laser lift-off can be performed on micro-LED die sizes greater than 2.2 mm×2.7 mm (width×length) and as defined herein for micro-LEDs. In another specific embodiment, wafer level laser lift-off is performed using a KrF excimer laser having a flat top beam having a beam size in a range from 200 micrometers×200 micrometers to 500 micrometers×500 micrometers. By using beam stitching, laser lift-off can be performed at the wafer level. As discussed above, when the laser lift-off procedure does not succeed in removing the sapphire substrate from the GaN interface, the sapphire substrate is adhered to the GaN interface and, unless it is removed, the wafer or die will have to be discarded, resulting in a loss of process yields, valuable material, and manufacturing time. Thus, one or more embodiments described herein solves an important problem by providing apparatus and methods to complete lift-off or removal of the sapphire substrate when the laser lift-off process has not resulted in removal of the sapphire substrate from the GaN interface, solving an expensive and difficult problem.

In one or more embodiments, in which the laser lift-off and the subsequent sapphire removal described by the method and apparatus described in this disclosure are performed at the wafer level, the wafer-size sapphire substrate is removed after the whole wafer has been processed. In other embodiments, in which the laser lift-off and the subsequent sapphire substrate removal described by the method and apparatus described in this disclosure are performed for each individual die, the dies are flip-chip mounted on the carrier 110 (or sub-mount)(e.g., as shown in FIG. 1), with the sapphire substrate facing upward. The laser is applied to each die, and the die-size sapphire chips are removed after the laser is incident on each die, leaving the semiconductor structure on the carrier 110.

Accordingly, the methods and apparatus described herein can be implemented at the die level (e.g. as shown in FIG. 1) or at the wafer level. According to one or more embodiments, after a laser lift-off process in which thermal decomposition aids in the separation of a sapphire substrate from a LED device, but the sapphire substrate has not been fully removed, a mechanical twisting method and/or apparatus can be used to complete removal of the sapphire substrate from the LED device. In one or more embodiments, a mechanical twisting method utilizes a customized tool described herein.

In one or more embodiments, after a laser lift-off process, a tape frame populated with LED devices undergoes ultraviolet cure, and then a pick and place (PnP) step is utilized to further process the LED devices to remove the sapphire substrate. Using a single LED device as an example, the LED device is picked from the ultraviolet cured tape frame and placed onto a carrier so that the sapphire substrate can be removed according to the apparatus and methods described herein.

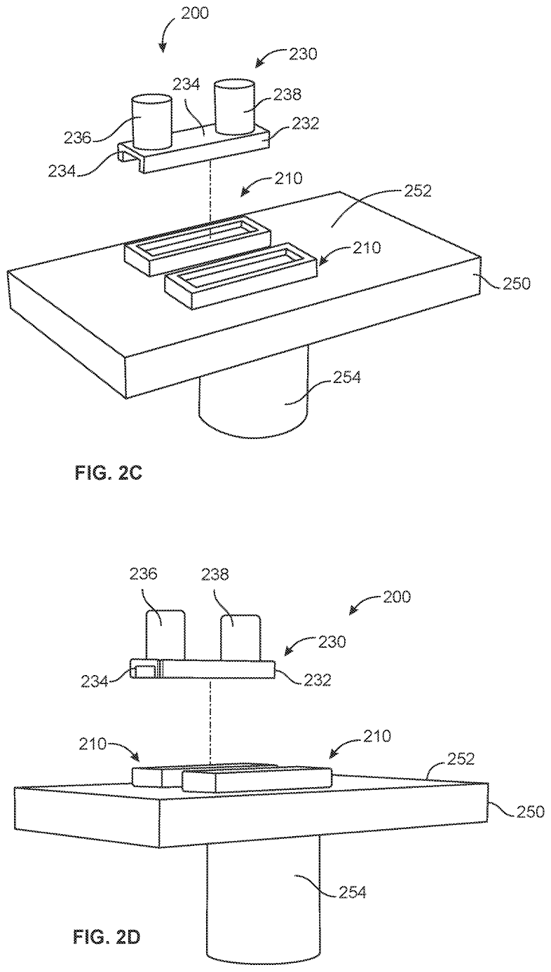

Referring now to FIGS. 2A-D, a first aspect of the disclosure pertains to a light emitting diode (LED) device sapphire substrate removal apparatus 200 comprising a holding plate 210 sized and shaped to receive and hold a carrier 110 of an LED device 101. The holding plate 210 comprises a recessed region 211 defining an area 212 configured to receive the carrier 110 and a raised edge 214 configured to hold the carrier 110 during a sapphire substrate 104 removal operation. The sapphire substrate removal apparatus 200 further comprises a sapphire substrate removal tool 230 movably spaced from the holding plate 210. The sapphire substrate removal tool 230 comprises a base 234 including a first rail 231 spaced apart from a second rail 232, the first rail 231 and the second rail 232 defining an area 235 sized and shaped to surround the sapphire substrate 104 and configured to remove the sapphire substrate 104 from the LED device 101 when the sapphire substrate removal tool 230 is twisted to separate the sapphire substrate 104 from the carrier 110 and layers disposed on the carrier 110 (e.g., interconnect 108, GaN interface 106). As shown in FIG. 2A, the holding plate 210 has an overall thickness or height “H” and the recessed region 211 defining the area 212 configured to receive the carrier 110 has a height “h” defined by the raised edge 214 having a top surface 215.

Referring now to FIGS. 2C-2D, the holding plate 210 is configured to be affixed to a processing platform 250 during the sapphire substrate removal operation. According to an embodiment, as shown in FIGS. 2C and 2D, there are two holding plates 210 affixed to a top surface 252 of the processing platform 250. The processing platform 250 is supported by a pedestal 254 which can extend, for example, from a surface of the processing platform 250 opposite the top surface 252. The disclosure is not limited to any number of holding plates 210 that can be affixed to the processing platform 250 during a sapphire removal operation. It will be appreciated that in a mass production or manufacturing operation, large numbers of LED devices, either at the die level as shown or at the wafer level, could be processed on a single platform. For example, the number of holding plates 210 affixed to the processing platform 250 can be in a range from one to several thousand, for example, 5,000.

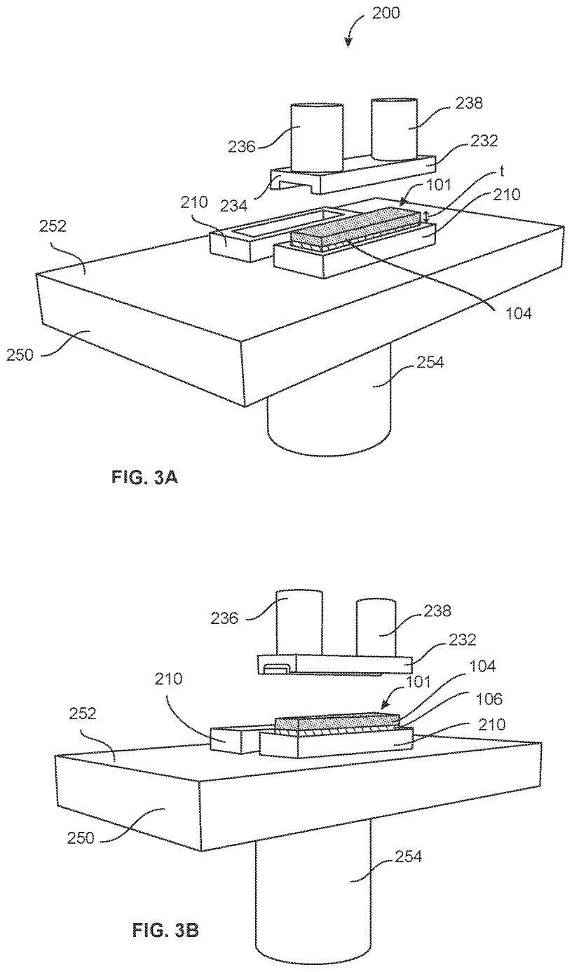

In one or more embodiments, for example as shown in FIG. 2A, the raised edge 214 comprises a first edge portion 214a separated from a second edge portion 214b at a distance D and configured to hold the carrier 110 during the sapphire substrate 104 removal operation. In some embodiments, the distance D is in a range from about 1 millimeters to about 350 millimeters, for example about 75 millimeters to about 350 millimeters or about 75 millimeters to about 300 millimeters. In other embodiments, the distance D is in a range of about 1 millimeters to about 75 millimeters, for example about 1 millimeters to about 50 millimeters, about 1 millimeters to about 25 millimeters, about 2 millimeters to about 25 millimeters or about 3 millimeters to about 15 millimeters. It will be understood that the respective dimensions and distances of the holding plate 210 and the sapphire substrate removal tool 230 according to one or more embodiments will be properly sized based on the dimensions of the sapphire substrate 104 and carrier 110 respectively. According to some embodiments, the respective dimensions and distances of the holding plate 210 and the sapphire substrate removal tool 230 allows clearance for the holding plate 210 to hold the carrier 110 and for the sapphire substrate removal tool 230 to hold the sapphire substrate 104. For example, the respective dimensions and distances can allow about 1 mm to about 2 mm of clearance for the holding plate 210 to hold the carrier 110 and for the sapphire substrate removal tool 230 to hold the sapphire substrate 104. In some embodiments, the first edge portion 214a and the second edge portion 214b each have a height h that is less than the thickness t of the sapphire substrate 104 so that the first edge portion 214a and second edge portion 214b do not contact the GaN interface 106 during sapphire substrate 104 removal (e.g., see FIGS. 3A-α). In some embodiments, the first edge portion 214a and the second edge portion 214b each have a height h that is less than about ¾ the thickness t of the sapphire substrate 104 or less than about % the thickness of the sapphire substrate 104.

FIGS. 3A-3B show the LED device sapphire substrate removal apparatus 200 with the LED device 101 placed in the recessed region 211 defining the area 212. The recessed region 211 defining the area 212 is sized and configured to receive the carrier 110, with the interconnect 108, the GaN interface 106, and the sapphire substrate 104 layered respectively thereon. In particular, the carrier 110 is securely received within the recessed region 211 defining the area 212 such that the carrier is 110 firmly held in place during a sapphire substrate removal operation. FIGS. 3A and 3B further show the sapphire substrate removal tool 230 positioned over the LED device 101.

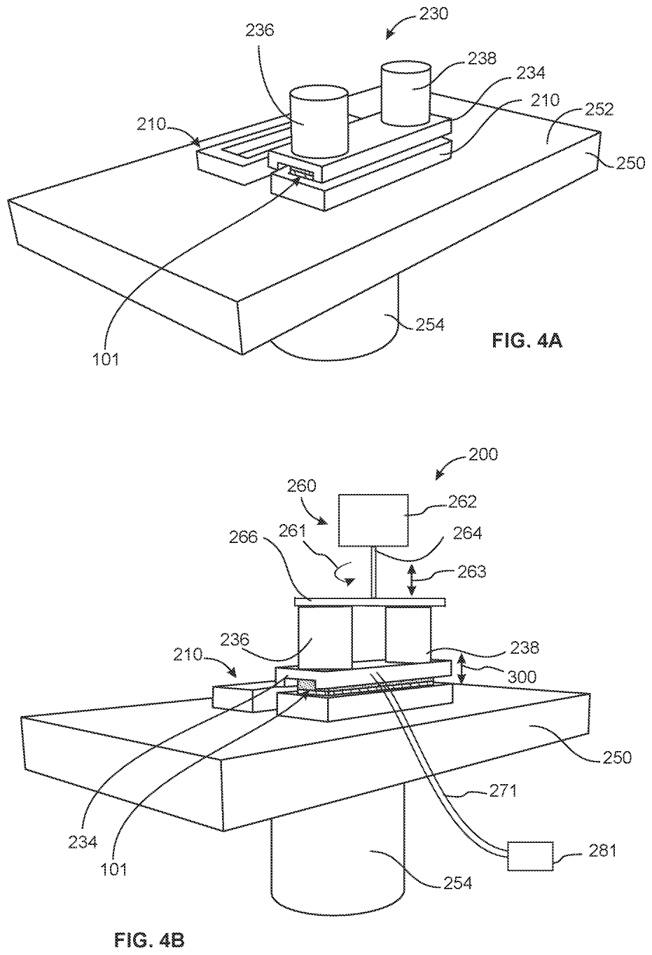

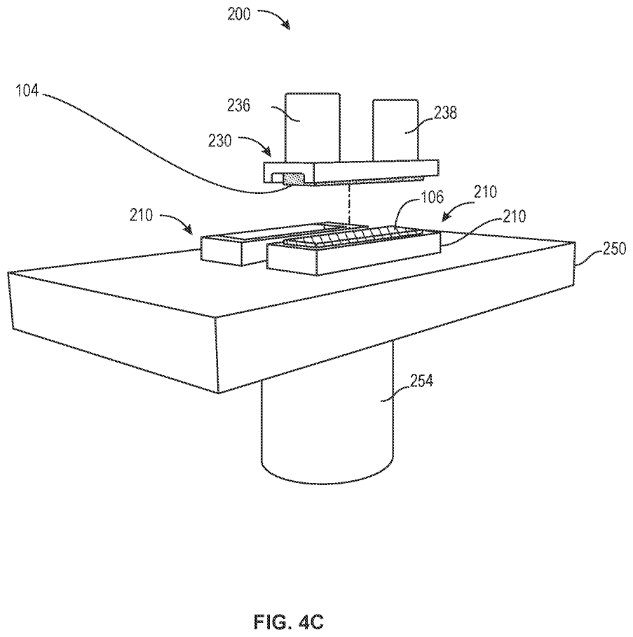

Referring now to FIG. 4A, the sapphire substrate removal tool 230 has been lowered onto the LED device and the sapphire substrate 104 is positioned between the first rail 231 and the second rail 232 of the sapphire substrate removal tool 230. Referring now to FIG. 4B, the sapphire substrate removal apparatus 200 is shown as further comprising a rotatable tool 260 including a motor 262 connected to a rotatable shaft 264. The rotatable tool 260 rotates in the direction of arrow 261 (or the opposite direction), and the rotatable tool 260 is configured to be engaged with the sapphire substrate removal tool 230 to move the sapphire substrate removal tool 230 in the direction of arrow 263 toward and away from the processing platform 250.

In the embodiment shown in FIG. 4B, the rotatable tool includes an attachment arm 266 configured to be engaged with the sapphire substrate removal tool 230. The sapphire substrate removal tool 230 further comprises a first post 236 and a second post 238 extending from the base 234 on a surface opposite the first and second rails 231, 232. As shown in FIG. 4B, the attachment arm 266 is attached to the first post 236 and the second post 238. In other embodiments, the attachment arm 266 can be attached to the base 234 of the sapphire substrate removal tool 230. The attachment arm 266 can be attached to the sapphire substrate removal tool 230 by any suitable attachment mechanism, such as by magnets, bolts, fasteners, detents, or the like. According to an embodiment, the attachment arm 266 can be attached to the sapphire substrate removal tool 230 by rails (not shown) extending from the attachment arm 266 that are configured to surround the first post 236 and the second post 238. In some embodiments, one or more of the first post 236 and the second post 238 are hollow.

In the embodiment shown in FIG. 4B, a first vacuum suction connection 271 fluidly connects the base 234 to a first vacuum source 281. In operation, when the sapphire substrate removal tool 230 is twisted to remove the sapphire substrate 104 from the carrier 110, the first vacuum source 281 is activated to suction any small pieces or shards that are created during the twisting of the sapphire substrate 104 and/or to retain the removed sapphire substrate 104 within the sapphire substrate removal tool 230. The suction from the first vacuum source 281 can subsequently be turned off and the removed sapphire substrate 104 discarded.

According to some embodiments, there is at least a second vacuum suction connection (not shown) that fluidly connects the base 234 to a second vacuum source (not shown). In some embodiments a single vacuum source may be provided, and the second vacuum source is not included. The first vacuum suction connection 271 (and any additional vacuum suction connections) can comprises any conventional connections for use with vacuum suction, such as a hose, a hard metal conduit, or the like that connects the first vacuum source 281 (and any additional vacuum sources) to the sapphire substrate removal tool 230. In one or more embodiments, the first vacuum source 281 (and any additional vacuum sources) comprises a vacuum pump.

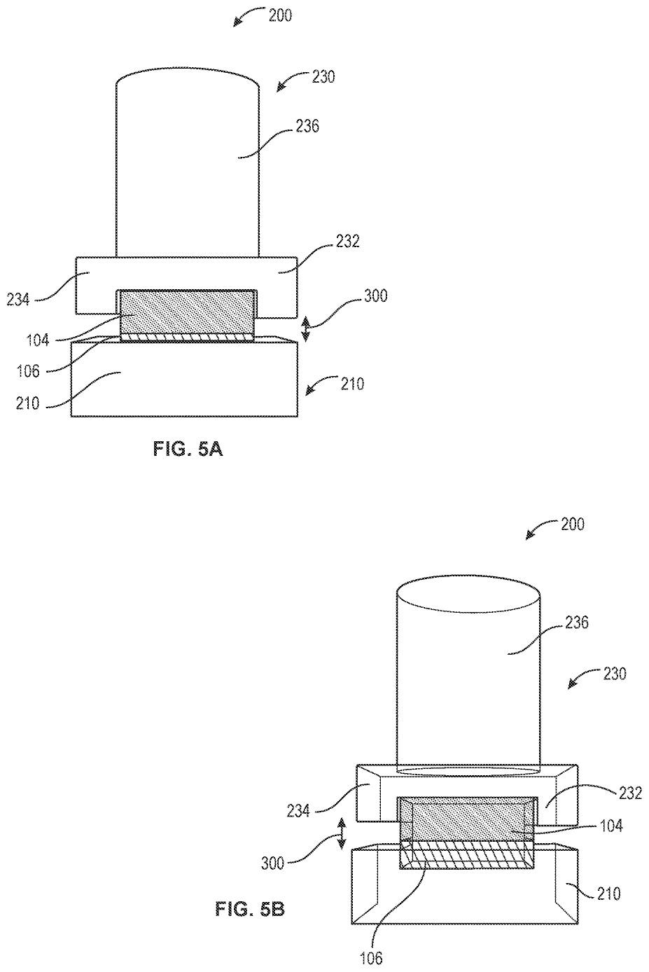

In one or more embodiments, the sapphire substrate removal tool 230 comprises a metal, such as stainless steel, and the holding plate 210 comprises a metal, such as stainless steel. FIGS. 5A and 5B show a side view of the sapphire substrate removal apparatus 200, with FIG. 5B in partial cross section to show the GaN interface 106, which is disposed on the interconnect 108 (not shown) which is adhered to the carrier 110, placed in the holding plate 210. Arrow 300 in FIGS. 4B and 5A and 5B indicate that the sapphire substrate removal tool 230 and the holding plate 210 are configured to be moved vertically with respect to each other. This can occur, for example, by providing a telescopic rotatable shaft 264, which allows the rotatable shaft 264 to extend and retract. In other embodiments, the rotatable tool 260 may be connected to a movable arm (not shown), for example a robotic arm that can raise and lower the rotatable tool 260 connected to the sapphire substrate removal tool 230.

After the carrier 110 is secured by the holding plate 210, the sapphire substrate removal tool 230 is lowered to a distance to prevent possible abrasion with the holding plate 110 and underlying carrier 110. The view shown in FIG. 5B illustrates the gap between the sapphire substrate removal tool 230 and the holding plate 210 to prevent surface friction.

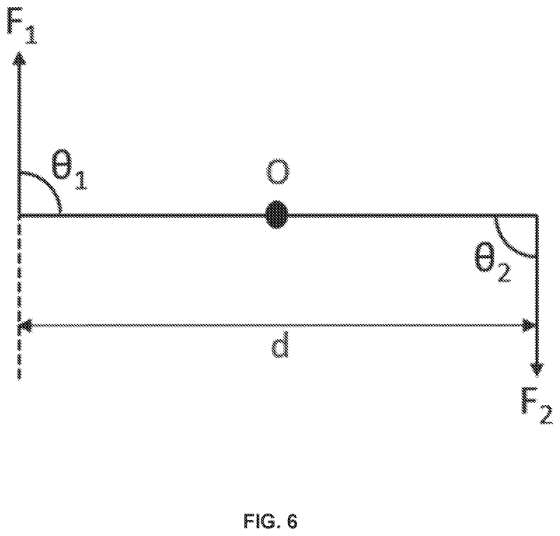

Referring now to FIG. 6, the twisting apparatus and method are influenced by a special case of torque called couple because there is a rotational motion about an axis with two equal parallel forces of magnitude acting exactly simultaneously at opposite directions as shown by the graph in FIG. 6.

The moment of couple is either clockwise or counter-clockwise relative to the pivot point (O). It is a cross product between distance of two forces (d) to the applied force (F) as shown in Equation 1.

$$\vec{M} = \frac{\vec{d}}{2} \times \vec{F} \qquad Equation 1$$

In cases where the applied force has an angle between vector d and F, the moment of couple can be calculated using Equation 2.

$$\vec{M} = \frac{\vec{d}}{2} \times \vec{F} sin θ \qquad Equation 2$$

According to one or more embodiments, there are two moments of couple because the forces applied are from the left and right ends of the sapphire substrate removal tool 230. The pivot point is at the center of the sapphire substrate removal tool 230, hence the distance on the left and right side are equal. Angles of the forces are the same since they are exactly perpendicular to the plane and both applied forces are assumed to be the same from identical source. The individual couples of the same magnitude produce a net moment of couple about point O and is calculated using Equation 3.

$${\vec{M}}_{1} = \frac{{\vec{d}}_{1}}{2} \times {\vec{F}}_{1} sin {θ}_{1} \qquad Equation 3$$

$${\vec{M}}_{2} = \frac{{\vec{d}}_{2}}{2} \times {\vec{F}}_{2} sin {θ}_{2}$$

$$Whereby ,$$

$${\vec{d}}_{1} = {\vec{d}}_{2}$$

$${\vec{F}}_{1} = {\vec{F}}_{2}$$

$$sin {θ}_{1} = sin {θ}_{2}$$

$$Hence ,$$

$${\vec{M}}_{1} = {\vec{M}}_{2}$$

$${\vec{M}}_{net} = {\vec{M}}_{1} + {\vec{M}}_{2} = dFsin θ$$

The sapphire substrate removal tool 230 exerts a net moment of couple about the center of the holder, creating the twisting effect. Vacuum suction in the sapphire substrate removal tool 230 will hold onto the sapphire substrate 104 and keep the sapphire substrate 104 disposed at a designated area. Finally, the sapphire substrate removal tool 230 is moved back to its initial position (e.g., as depicted in FIG. 40). The LED device 101 with the sapphire substrate 104 now removed is picked and placed onto a new tape frame before proceeding to the next processing step.

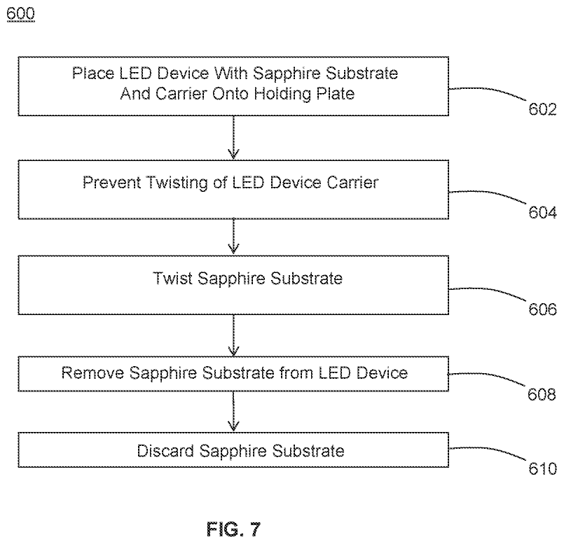

Referring now to FIG. 7, another aspect of the disclosure pertains to a method 600 of removing a sapphire substrate 104 from an LED device 101. In one embodiment, the method 600 comprises placing the LED device 101 comprising a sapphire substrate 104 and a carrier 110 onto a holding plate 210 sized and shaped to hold the carrier 110 of an LED device 110 (operation 602). The method can further comprise preventing twisting of the LED device carrier 110 (operation 604) and then twisting the sapphire substrate 104 (operation 606), for example, by applying a twisting force to the sapphire substrate 104 to separate the sapphire substrate 104 from the carrier 110. The sapphire substrate 104 is then removed from the LED device 101 (operation 608), and the sapphire substrate 104 is discarded (operation 610).

In some embodiments, the method further comprises affixing a holding plate 210 to a support (e.g., a processing platform 250) prior to applying the twisting force to prevent the holding plate 210 from twisting when removing the sapphire substrate 104 from the LED device 101. As described above, in some embodiments, a sapphire substrate removal tool 230 is utilized to apply the twisting force to the sapphire substrate 104. In one or more embodiments, the method includes applying suction to the sapphire substrate removal tool 230 to pick up the LED device 101 from a first location and place the LED device 101 onto the holding plate 210.

In some embodiments, the method includes using a motor 262 to rotate the sapphire substrate removal tool 230. The method can further comprise using the components of the sapphire substrate removal apparatus 200 described herein, for example, the holding plate 210 comprising a recessed region 211 defining an area 212 configured to receive the carrier 110 and a raised edge 210 configured to hold the carrier 110 during a sapphire substrate removal operation. Further, the sapphire substrate removal tool 230 can be used, comprising a base 234 including a first rail 231 spaced apart from a second rail 232, the first rail 231 and the second rail 232 defining an area 235 sized and shaped to surround the sapphire substrate 104 and configured to remove the sapphire substrate 104 from the LED device 101 when the sapphire substrate removal tool 230 is twisted to separate the sapphire substrate 104 from the carrier 110.

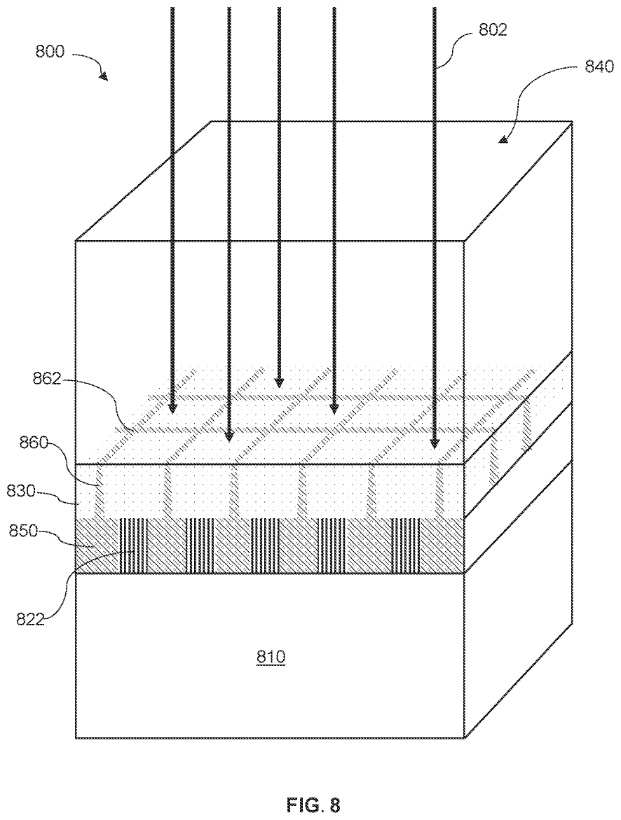

Embodiments of the disclosure can be utilized to remove a sapphire substrate after a laser lift-off procedure from an LED die including a trenched metal grid. In an exemplary embodiment, FIG. 8 illustrates in perspective view a structure 800 that allows for laser lift-off removal of a sapphire substrate 840 from contact with the LED die including a trenched metal grid 862. The structure 800 includes an LED die with semiconductor layers 830 (in which the uppermost layer is a GaN interface as described above) attached to a CMOS chip or wafer 810. Electrical and mechanical connection between the CMOS chip or wafer 810 and the semiconductor layers 830 is provided by electrically conductive pillars 822. The pillars define a cavity or gap that can be filled with an underfill material 850 to improve mechanical stability and attachment, and also improve electrical isolation.

In this embodiment the semiconductor layers 830 include the trenched metal 860 that forms a trenched metal grid 862. In effect, trenches can help define a plurality of spaced mesas that, in turn, define pixels, with each of the plurality of spaced mesas comprising the semiconductor layers 830 and each of the spaced mesas having a height less than or equal to their width. The trenched metal 860, which is deposited in a space between each of the plurality of spaced mesas, provides optical isolation between each of the spaced mesas and allows electrical contact with sidewalls of the GaN LED. In one embodiment, electrical contact can include electrically contacting the n-type layer of each of the spaced mesas along sidewalls of the n-type layers. The space between each of the plurality of spaced mesas can result in a pixel pitch in a range of from about 1 μm to about 100 μm and space between adjacent edges of the p-contact layer of less than about 10% of the pixel pitch when the pixel pitch is in a range of from about 10 μm to about 100 μm, and when the pixel pitch is in a range of about 1 μm to about 10 μm, the space gap is less than or equal to about 5 μm and greater than about 0.5 μm.

In some embodiments, the trenched metal 860 comprises a reflective metal. In some embodiments, the trenched metal 850 width is less than or equal to about 4 μm and greater than about 0.5 μm, or less than or equal to about 3 μm and greater than about 0.5 μm. In some embodiments, the plurality of spaced mesas between the trenched metal grid 862 is arranged into pixels, and the pixel pitch ranges from about 5 μm to about 100 μm, or from about 30 μm to about 50 μm. In some embodiments, the semiconductor layers 830 have a thickness in a range of from about 2 μm to about 50 μm, for example from about 2 μm to about 30 μm, or about 2 μm to about 20 μm. In some embodiments, the thickness of the sapphire substrate 840 is in a range of from about 100 μm to about 800 μm.

Since the trenched metal 860 is attached between the sapphire substrate 840 and the semiconductor layers 830 of the LED die, sapphire lift-off requires breaking connection with the trenched metal 860. In this embodiment, laser light 802 decomposes the GaN (or other semiconductor layer 830 material) to create separation from the sapphire substrate 840. While the laser energy is not high enough to cause decomposition and direct release of the trenched metal 860, in regions where the area of semiconductor layer 830 material (e.g., GaN) is sufficiently greater than the area of the trenched metal 860, the force of nitrogen gas expansion from decomposition of semiconductor layer 830 material (e.g., GaN) causes separation of trenched metal 860 from the sapphire substrate 840. The apparatus and methods described herein can be used to remove the sapphire substrate 840 when the sapphire substrate remains adhered to the GaN interface (or other material) of the semiconductor layers 830 after laser lift-off, providing post laser lift-off processes and apparatus to complete removal of the sapphire substrate 840 from the LED die, solving a difficult and costly problem.

### Embodiments

Various embodiments are listed below. It will be understood that the embodiments listed below may be combined with all aspects and other embodiments in accordance with the scope of the disclosure, and the combination of embodiments is not limited to the combinations provided immediately below.

Embodiment 1 is a light emitting diode (LED) device sapphire substrate removal apparatus comprising a holding plate sized and shaped to hold a carrier of an LED device, the holding plate comprising a recessed region defining an area configured to receive the carrier and a raised edge configured to hold the carrier during removal of a sapphire substrate from the LED device; and a sapphire substrate removal tool movably spaced from the holding plate, the sapphire substrate removal tool comprising a base including a first rail spaced apart from a second rail, the first rail and the second rail defining an area sized and shaped to surround the sapphire substrate and configured to remove the sapphire substrate from the LED device when the sapphire substrate removal tool is rotated to separate the sapphire substrate from the carrier.

Embodiment 2 pertains to the LED device sapphire substrate removal apparatus of embodiment 1, further comprising a processing platform, wherein the holding plate is affixed to the processing platform during removal of the sapphire substrate from the LED device.

Embodiment 3 pertains to the LED device sapphire substrate removal apparatus of embodiment 1 or 2, wherein the raised edge comprises a first edge portion separated from a second edge portion at a distance and configured to hold the carrier while removing the sapphire substrate from the LED device.

Embodiment 4 pertains to the LED device sapphire substrate removal apparatus of embodiment 3, wherein the distance in a range from about 1 millimeter to about 300 millimeters.

Embodiment 5 pertains to the LED device sapphire substrate removal apparatus of embodiment 3, wherein the distance is in a range from about 2 millimeters to about 25 millimeters.

Embodiment 6 pertains to the LED device sapphire substrate removal apparatus of embodiments 2-5, the raised edge comprising a peripheral edge defining an area configured to hold the carrier while removing the sapphire substrate from the LED device.

Embodiment 7 pertains to the LED device sapphire substrate removal apparatus of embodiments 1-6, wherein the area is sized to hold a carrier having a length or a width dimension from about 1 millimeter to about 300 millimeters.

Embodiment 8 pertains to the LED device sapphire substrate removal apparatus of embodiments 1-7, wherein the area is sized to hold a carrier having a length or a width dimension in a range of from about 2 millimeters to about 25 millimeters.

Embodiment 9 pertains to the LED device sapphire substrate removal apparatus of embodiments 1-8, the sapphire substrate removal tool further comprising a vacuum suction connection.

Embodiment 10 pertains to the LED device sapphire substrate removal apparatus of embodiment 9, further comprising a vacuum source in communication with the vacuum suction connection.

Embodiment 11 pertains to the LED device sapphire substrate removal apparatus of embodiment 10, wherein the vacuum source comprises a vacuum pump.

Embodiment 12 pertains to the LED device sapphire substrate removal apparatus of embodiments 1-11, wherein the sapphire substrate removal tool comprises a metal.

Embodiment 13 pertains to the LED device sapphire substrate removal apparatus of embodiments 1-12, further comprising a first post and a second post extending from the base, wherein the first post and the second post extend from a surface of the base opposite the first rail and second rail.

Embodiment 14 pertains to the LED device sapphire substrate removal apparatus of embodiment 13, wherein at least on of the first post and the second post is hollow.

Embodiment 15 pertains to the LED device sapphire substrate removal apparatus of embodiment 9, further comprising a first post and a second post, the first post and the second post being hollow, and the vacuum suction connection is connected to at least one of the first post and the second post.

Embodiment 16 pertains to the LED device sapphire substrate removal apparatus of embodiments 1-15, further comprising a rotatable tool configured to be engaged with the sapphire substrate removal tool.

Embodiment 17 pertains to the LED device sapphire substrate removal apparatus of embodiment 13, further comprising a rotatable tool configured to be engaged with the sapphire substrate removal tool.

Embodiment 18 pertains to the LED device sapphire substrate removal apparatus of embodiment 16, wherein the rotatable tool comprises a motor and a shaft.

Embodiment 19 pertains to the LED device sapphire substrate removal apparatus of embodiments 1-18, wherein the sapphire substrate removal tool and the holding plate are configured to be movable vertically with respect to each other.

Embodiment 20 pertains to a method of removing a sapphire substrate from an LED device, the method comprising: placing the LED device comprising the sapphire substrate and a carrier onto a holding plate sized and shaped to hold the carrier of the LED device; and applying a twisting force to the sapphire substrate to separate the sapphire substrate from the carrier.

Embodiment 21 pertains to the method of embodiment 20, further comprising affixing the holding plate to a support prior to applying the twisting force to prevent the holding plate from twisting when removing the sapphire substrate from the LED device.

Embodiment 22 pertains to the method of embodiments 20 or 21, wherein a sapphire substrate removal tool is utilized to apply the twisting force to the sapphire substrate.

Embodiment 23 pertains to the method of embodiments 20-22, further comprising applying suction to the sapphire substrate removal tool to pick the LED device from a first location and place the LED device onto the holding plate.

Embodiment 24 pertains to the method of embodiments 20-23, further comprising using a motor to rotate the sapphire substrate removal tool.

Embodiment 25 pertains to the method of embodiments 20-24, wherein the holding plate comprises a recessed region defining an area configured to receive the carrier and a raised edge configured to hold the carrier while removing the sapphire substrate from the LED device, and placing the LED device onto the holding plate comprises placing the carrier into the recessed region defining the area such that the raised edge holds the carrier.

Embodiment 26 pertains to the method of embodiment 25, wherein the sapphire substrate removal tool comprises a base including a first rail spaced apart from a second rail, the first rail and the second rail defining an area sized and shaped to surround the sapphire substrate and configured to remove the sapphire substrate from the LED device when the sapphire removal tool is twisted to separate the sapphire substrate from the carrier, and the method further comprises, prior to applying the twisting force to the sapphire substrate, positioning the first rail and second rail to surround the sapphire substrate.

Embodiment 27 pertains to the method of embodiments 25-26, wherein the raised edge comprises at a first edge portion separated from a second edge portion at a distance and configured to hold the carrier while removing the sapphire substrate from the LED device.

Embodiment 28 pertains to the method of embodiments 25-27, wherein the distance is in a range from about 1 millimeter to about 300 millimeters.

Embodiment 29 pertains to the method of embodiments 25-27, wherein the distance is in a range of from about 2 millimeters to about 25 millimeters.

Embodiment 30 pertains to the method of embodiments 25-29, wherein the raised edge comprises a peripheral edge defining an area configured to hold the carrier while removing the sapphire substrate from the LED device.

Embodiment 31 pertains to the method of embodiment 30, wherein the area is sized to hold a carrier having a length or a width dimension in a range from about 1 millimeters to about 300 millimeters.

Embodiment 32 pertains to the method of embodiment 30, wherein the area is sized to hold a carrier having a length or a width dimension in a range from about 2 millimeters to about 25 millimeters.

Embodiment 33 pertains to the method of embodiments 22-32, wherein the sapphire substrate removal tool comprises a metal.

Embodiment 34 pertains to the method of embodiments 22-33, the sapphire substrate removal tool further comprises a first post and a second post extending from the base, wherein the first post and the second post extend from a surface of the base opposite the first rail and second rail.

Embodiment 35 pertains to the method of embodiment 34, wherein at least one of the first post and the second post is hollow.

Embodiment 36 pertains to the method of embodiment 35, further comprising attaching a vacuum suction connection to at least one of the first post and the second post.

Embodiment 37 pertains to the method of embodiment 36, further comprising a rotatable tool configured to engage with the sapphire substrate removal tool, and applying the twisting force to the sapphire substrate comprises causing the rotatable tool to rotate the sapphire substrate removal tool.

Embodiment 38 pertains to the method of claim 37, wherein the rotatable tool comprises the motor and a shaft connected to the motor and connectable to the sapphire substrate removal tool.

Embodiment 39 pertains to the method of embodiments 22-38, wherein the sapphire substrate removal tool and the holding plate are configured to be movable vertically with respect to each other, and applying a twisting force to the sapphire substrate to separate the sapphire substrate from the carrier further comprises moving the sapphire substrate removal tool and the holding plate vertically with respect to each other to separate the sapphire substrate from the carrier.

The use of the terms “a” and “an” and “the” and similar referents in the context of describing the materials and methods discussed herein (especially in the context of the following claims) are to be construed to cover both the singular and the plural, unless otherwise indicated herein or clearly contradicted by context. Recitation of ranges of values herein are merely intended to serve as a shorthand method of referring individually to each separate value falling within the range, unless otherwise indicated herein, and each separate value is incorporated into the specification as if it were individually recited herein. All methods described herein can be performed in any suitable order unless otherwise indicated herein or otherwise clearly contradicted by context. The use of any and all examples, or exemplary language (e.g., “such as”) provided herein, is intended merely to better illuminate the materials and methods and does not pose a limitation on the scope unless otherwise claimed. No language in the specification should be construed as indicating any non-claimed element as essential to the practice of the disclosed materials and methods.

Reference throughout this specification to the terms first, second, third, etc. may be used herein to describe various elements, and these elements should not be limited by these terms. These terms may be used to distinguish one element from another.

Reference throughout this specification to a layer, region, or substrate as being “on” or extending “onto” another element, means that it may be directly on or extend directly onto the other element or intervening elements may also be present. When an element is referred to as being “directly on” or extending “directly onto” another element, there may be no intervening elements present. Furthermore, when an element is referred to as being “connected” or “coupled” to another element, it may be directly connected or coupled to the other element and/or connected or coupled to the other element via one or more intervening elements. When an element is referred to as being “directly connected” or “directly coupled” to another element, there are no intervening elements present between the element and the other element. It will be understood that these terms are intended to encompass different orientations of the element in addition to any orientation depicted in the figures.

Relative terms such as “below,” “above,” “upper,”, “lower,” “horizontal” or “vertical” may be used herein to describe a relationship of one element, layer, or region to another element, layer, or region as illustrated in the figures. It will be understood that these terms are intended to encompass different orientations of the device in addition to the orientation depicted in the figures.

Reference throughout this specification to “one embodiment,” “certain embodiments,” “one or more embodiments” or “an embodiment” means that a particular feature, structure, material, or characteristic described in connection with the embodiment is included in at least one embodiment of the disclosure. Thus, the appearances of the phrases such as “in one or more embodiments,” “in certain embodiments,” “in one embodiment” or “in an embodiment” in various places throughout this specification are not necessarily referring to the same embodiment of the disclosure. Furthermore, the particular features, structures, materials, or characteristics may be combined in any suitable manner in one or more embodiments.

Although the disclosure herein has been described with reference to particular embodiments, it is to be understood that these embodiments are merely illustrative of the principles and applications of the present disclosure. It will be apparent to those skilled in the art that various modifications and variations can be made to the method and apparatus of the present disclosure without departing from the spirit and scope of the disclosure. Thus, it is intended that the present disclosure include modifications and variations that are within the scope of the appended claims and their equivalents. Therefore, it is understood the method and apparatus of the present disclosure is not to be limited to the specific embodiments disclosed, and that modifications and embodiments are intended to be included within the scope of the appended claims. It is also understood that other embodiments of the method and apparatus of the present disclosure may be practiced in the absence of an element/step not specifically disclosed herein.

1. A method of removing a sapphire substrate from a light emitting diode (LED) device, the method comprising:
placing the LED device comprising the sapphire substrate and a carrier onto a holding plate sized and shaped to hold the carrier of the LED device; and
applying a twisting force to the sapphire substrate to separate the sapphire substrate from the carrier.

2. The method of claim 1, further comprising affixing the holding plate to a support prior to applying the twisting force to prevent the holding plate from twisting when removing the sapphire substrate from the LED device.

3. The method of claim 2, wherein a sapphire substrate removal tool is utilized to apply the twisting force to the sapphire substrate.

4. The method of claim 3, further comprising applying suction to the sapphire substrate removal tool to pick the LED device from a first location and place the LED device onto the holding plate.

5. The method of claim 4, further comprising using a motor to rotate the sapphire substrate removal tool.

6. The method of claim 3, wherein the holding plate comprises a recessed region defining an area configured to receive the carrier and a raised edge configured to hold the carrier while removing the sapphire substrate from the LED device, and placing the LED device onto the holding plate comprises placing the carrier into the recessed region defining the area such that the raised edge holds the carrier.

7. The method of claim 6, wherein the sapphire substrate removal tool comprises a base including a first rail spaced apart from a second rail, the first rail and the second rail defining an area sized and shaped to surround the sapphire substrate and configured to remove the sapphire substrate from the LED device when the sapphire substrate removal tool is twisted to separate the sapphire substrate from the carrier, and the method further comprises, prior to applying the twisting force to the sapphire substrate, positioning the first rail and second rail to surround the sapphire substrate.

8. The method of claim 7, wherein the raised edge comprises at a first edge portion separated from a second edge portion at a distance and configured to hold the carrier while removing the sapphire substrate from the LED device.

9. The method of claim 8, wherein the distance is in a range of from about 1 millimeter to about 300 millimeters.

10. The method of claim 8, wherein the distance is in a range of from about 2 millimeters to about 25 millimeters.

11. The method of claim 7, wherein the raised edge comprises a peripheral edge defining an area configured to hold the carrier while removing the sapphire substrate from the LED device.

12. The method of claim 11, wherein the area is sized to hold the carrier having a length or a width dimension in a range from about 1 millimeter to about 300 millimeters.

13. The method of claim 11, wherein the area is sized to hold the carrier having a length or a width dimension in a range from about 2 millimeters to about 25 millimeters.

14. The method of claim 7, wherein the sapphire substrate removal tool comprises a metal.

15. The method of claim 7, wherein the sapphire substrate removal tool further comprises a first post and a second post extending from a surface of the base opposite the first rail and second rail.

16. The method of claim 15, wherein at least one of the first post and the second post is hollow.

17. The method of claim 16, further comprising attaching a vacuum suction connection to at least one of the first post and the second post.

18. The method of claim 7, further comprising a rotatable tool configured to engage with the sapphire substrate removal tool, and applying the twisting force to the sapphire substrate comprises causing the rotatable tool to rotate the sapphire substrate removal tool.

19. The method of claim 18, wherein the rotatable tool comprises a motor and a shaft connected to the motor and connectable to the sapphire substrate removal tool.

20. The method of claim 19, wherein the sapphire substrate removal tool and the holding plate are configured to be movable vertically with respect to each other, and applying a twisting force to the sapphire substrate to separate the sapphire substrate from the carrier further comprises moving the sapphire substrate removal tool and the holding plate vertically with respect to each other to separate the sapphire substrate from the carrier.
